(19) United States
(12) Patent Application Publication
(10) Pub. No.: US 2024/0395544 A1
(43) Pub. Date: Nov. 28, 2024

(54) DEPOSITION AND TREATMENT OF NANO-GRAPHENE AT LOW TEMPERATURES

(71) Applicant: Lam Research Corporation, Fremont, CA (US)

(72) Inventors: Kashish SHARMA, Tigard, OR (US); Bhadri N. VARADARAJAN, Beaverton, OR (US)

(21) Appl. No.: 18/694,600

(22) PCT Filed: Sep. 29, 2022
(86) PCT No.: PCT/US2022/077307

§ 371 Date: Mar. 22, 2024

Related U.S. Application Data
(60) Provisional application No. 63/261,904, filed on Sep. 30, 2021.

(51) Int. Cl. H01L 21/02; C23C 16/26; C23C 16/56; H01J 37/32

(52) U.S. Cl. CPC H01L 21/02527; C23C 16/26; C23C 16/56; H01J 37/32357; H01J 37/32449; H01L 21/0262; H01L 21/02664; H01J 2237/332

(57) ABSTRACT

A nano-graphene layer is deposited on a metal surface of a semiconductor substrate at a temperature compatible with back-end-of-line semiconductor processing. The nano-graphene layer is initially deposited by flowing hydrocarbon precursors such as hydrocarbon precursors with alkene or alkyne groups at a temperature range equal to or less than about 400° C. to adsorb on a metal surface such as cobalt, ruthenium, or copper. The nano-graphene layer is treated by exposure to plasma to deposit and form high-quality nano-graphene on the metal surface. The treatment may include exposure to remote plasma such as a remote inert gas plasma.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Graphene is an allotrope of carbon in which the atoms are arrayed in a single atom sheet in a regular hexagonal pattern. Graphene has attracted interest in many fields and industries because of its high electrical conductivity, high thermal conductivity, good mechanical strength and toughness, optical transparency, and high electron mobility, among other favorable properties. Interest is growing in graphene in the semiconductor industry.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Disclosed herein is a method of depositing nano-graphene. The method includes flowing one or more hydrocarbon precursors into a reaction chamber to adsorb onto a metal layer of a substrate at a temperature equal to or less than about 400° C., where the metal layer interacts with the adsorbed hydrocarbon precursors to produce a nano-graphene layer on the metal layer, and exposing the nano-graphene layer to plasma to treat the nano-graphene layer on the metal layer of the substrate.

In some implementations, exposing the nano-graphene layer to plasma comprises treating the nano-graphene layer with inert gas plasma generated from a remote plasma source to form a high-quality nano-graphene layer. In some implementations, the metal layer comprises copper, ruthenium, nickel, molybdenum, cobalt, or combinations thereof. In some implementations, the metal layer comprises cobalt. In some implementations, the one or more hydrocarbon precursors comprise an unsubstituted alkene, a substituted alkene, aromatic hydrocarbon, an unsubstituted alkyne, or substituted alkyne group. In some implementations, the one or more hydrocarbon precursors comprise toluene, benzene, ethylene, propylene, butene, pentene, pentadiene, hexene, acetylene, propyne, butyne, or pentyne. In some implementations, the one or more hydrocarbon precursors comprise propadiene, allene, cyclopropene, 1,3-butadiene, 1,2-butadiene, cyclobutene, isoprene, piperylene, cyclohexene, dimethylbutadiene, 1,5-hexadiene, norbornene, or 1,7-octadiene. In some implementations, flowing the one or more hydrocarbon precursors into the reaction chamber comprises flowing the one or more hydrocarbon precursors with hydrogen-helium (H₂—He) into the reaction chamber. In some implementations, flowing the one or more hydrocarbon precursors into the reaction chamber comprises flowing the one or more hydrocarbon precursors with oxygen (O₂) into the reaction chamber. In some implementations, exposing the nano-graphene layer to plasma comprises exposing the nano-graphene layer to remote hydrogen-helium plasma. In some implementations, exposing the nano-graphene layer to plasma comprises exposing the nano-graphene layer to remote oxygen-helium plasma. In some implementations, a thickness of the metal layer is between 10 Å and about 20 Å. In some implementations, the method further includes pretreating the metal layer with plasma to reduce metal oxides from the metal layer prior to flowing the one or more hydrocarbon precursors into the reaction chamber. In some implementations, the method further includes repeating operations of flowing one or more hydrocarbon precursors into the reaction chamber and plasma exposure in order to form a desired thickness of the nano-graphene layer on the metal layer of the substrate.

Also provided herein is a method of depositing nano-graphene. The method includes flowing carbon-containing radicals into a reaction chamber to expose a metal layer of a substrate to the carbon-containing radicals, where the carbon-containing radicals are generated from a source gas comprising one or more hydrocarbon precursors in a remote plasma source upstream of the reaction chamber, and where the metal layer interacts with the carbon-containing radicals to produce a nano-graphene layer on the metal layer, and exposing the nano-graphene layer to plasma to treat the nano-graphene layer on the metal layer of the substrate.

In some implementations, exposing the nano-graphene layer to plasma comprises treating the nano-graphene layer with inert gas plasma generated from a remote plasma source to form a high-quality nano-graphene layer. In some implementations, the source gas comprises a mixture of hydrogen (H₂) and the one or more hydrocarbon precursors, where carbon-containing radicals and hydrogen radicals are generated in the remote plasma source and flowed into the reaction chamber. In some implementations, the metal layer comprises copper, ruthenium, nickel, molybdenum, cobalt, or combinations thereof. In some implementations, the metal layer comprises cobalt. In some implementations, the one or more hydrocarbon precursors comprise an unsubstituted alkene, a substituted alkene, aromatic hydrocarbon, an unsubstituted alkyne, or substituted alkyne group. In some implementations, the one or more hydrocarbon precursors comprise toluene, benzene, ethylene, propylene, butene, pentene, pentadiene, hexene, acetylene, propyne, butyne, or pentyne. In some implementations, the one or more hydrocarbon precursors comprise propadiene, allene, cyclopropene, 1,3-butadiene, 1,2-butadiene, cyclobutene, isoprene, piperylene, cyclohexene, dimethylbutadiene, 1,5-hexadiene, norbornene, or 1,7-octadiene. In some implementations, exposing the nano-graphene layer to plasma comprises exposing the nano-graphene layer to remote hydrogen-helium plasma or remote oxygen-helium plasma.

### BRIEF DESCRIPTION OF THE DRAWINGS

FIG. 1 illustrates a cross-sectional schematic of an example substrate having a metal layer with graphene deposited thereon according to some implementations.

FIG. 2 illustrates a cross-sectional schematic of an example substrate having a cobalt layer on a copper layer, with nano-graphene deposited on the cobalt layer according to some implementations.

FIG. 3A illustrates a graph showing Raman spectrum of an example amorphous carbon layer according to some implementations.

FIG. 3B illustrates a graph showing Raman spectrum of an example nano-graphene layer on a metal layer according to some implementations.

FIG. 3C illustrates a graph showing Raman spectrum of an example graphene layer on a metal layer according to some implementations.

FIG. 4A illustrates a flow chart of an example method of a deposition and treatment process for depositing nano-graphene according to some implementations.

FIG. 4B illustrates a flow chart of an example method of a deposition and treatment process for depositing nano-graphene according to some other implementations.

FIG. 5A illustrates a flow diagram of an example method for depositing nano-graphene according to some implementations.

FIG. 5B illustrates a flow diagram of an example method for depositing nano-graphene according to some other implementations.

FIG. 6 illustrates a schematic diagram of an example plasma processing apparatus with a remote plasma source according to some implementations.

FIG. 7 shows a schematic diagram of an example plasma processing apparatus having a reaction chamber with pedestal heating according to some implementations.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

### Introduction

There is a growing interest in synthesizing graphene films in semiconductor applications. However, there are many challenges associated with production of graphene in sufficient quantities and under suitable conditions for semiconductor integration. Many production methods suffer from low surface coverage because of the difficulty of growing graphene with minimal defects. Thus, scalability to produce large-area graphene films represents a particular problem, especially large-area graphene films on semiconductor wafers. Furthermore, graphene films are typically grown by thermal chemical vapor deposition (CVD). Thermal CVD methods are generally favored for synthesis of large-area, high-quality graphene. However, thermal CVD of graphene is often performed at elevated temperatures, which may not necessarily be compatible with semiconductor applications. Under such high temperatures, various materials such as semiconductors and metals on semiconductor wafers may be physically damaged.

Thermal CVD is a common method of depositing graphene. The thermal CVD process involves at least two steps: activation of gaseous precursors and chemical reaction to form a stable, solid film on a suitable substrate. In thermal CVD, activation of gaseous precursors can occur by thermal decomposition. At elevated temperatures, hydrocarbon precursors thermally decompose and adsorb onto a substrate surface. Hydrocarbon radicals are chemically reactive and may interact with the substrate surface. The substrate surface may be a metal surface that acts as a catalyst for nucleation and growth of graphene. Without being limited by any theory, the catalytic metal surface may dehydrogenate the hydrocarbon radicals so that carbon atoms may bond with other carbon atoms, thereby promoting nucleation and growth of graphene. Various transition metals such as copper have been recognized as catalysts for nucleation and growth of graphene.

Activation of hydrocarbon species and graphene growth can depend on factors such as temperature and the metal surface on which graphene is grown. In addition, graphene growth can depend on carbon solubility on the metal surface. Carbon solubility is the extent that carbon will dissolve into a solid material (e.g., metal) without forming a separate phase. If the metal has high carbon solubility, carbon more easily dissolves in the metal and tends to precipitate on the metal surface. This generally leads to less uniform graphene layers and more microstructural defects owing to multiple nucleation sites and an unpredictable quantity of segregated carbon on the metal surface. Nickel substrates, for example, have high carbon solubility and typically lead to multiple layers of low-quality graphene or disordered carbon. If the metal has low carbon solubility, carbon less easily dissolves in the metal and results in an extensive surface migration of carbon adatoms on the metal surface and minimal diffusion into bulk metal. This generally leads to more uniform graphene layers and fewer microstructural defects owing to more controlled growth. Copper substrates, for example, have low carbon solubility and result in epitaxial growth of high-quality graphene. The high-quality graphene may be grown as a single layer, bilayer, or few-layer graphene film.

Plasma-enhanced chemical vapor deposition (PECVD) is another method of depositing graphene. Whereas thermal CVD methods activate hydrocarbon precursors by thermal decomposition, energized electrons generated by plasma cause ionization, excitation, and dissociation of hydrocarbon precursors in PECVD methods. The plasma may be formed in-situ or remotely. Typically, hydrocarbon precursors (e.g., methane) are activated in a plasma and a substrate is exposed to the plasma. The plasma may be generated using a radio-frequency (RF) plasma source, microwave (MW) plasma source, surface wave (SW) plasma source, or remote plasma source. By way of an example, molecular hydrogen and methane gas may be introduced in a reaction chamber and direct RF plasma may be ignited to promote graphene growth on a substrate. With PECVD, graphene growth in some PECVD methods may be performed at lower temperatures compared to thermal CVD methods. Moreover, graphene growth in some PECVD methods may be accomplished on non-metal substrates such as dielectric materials. In other words, plasma-based methods may deposit graphene in the absence of metal catalysts. Plasma-based methods may deposit graphene at lower temperatures and without the assistance of metal catalysts.

### Deposition of Nano-Graphene

Graphene is characterized as a single layer of carbon atoms arranged in a two-dimensional sheet arranged in a hexagonal lattice structure. Singular units of graphene are referred to as nano-graphene. Put another way, nano-graphenes are graphene fragments. Generally speaking, such graphene fragments or nano-graphenes have a diameter less than about 100 nm while graphene typically has a diameter that is equal to or greater than about 100 nm. Nano-graphenes have been attracting widespread interest and can be tailored to specific properties including electronic, optical, and magnetic properties. For example, nano-graphenes can be used as non-linear optical materials in optoelectronic devices, used as gas detectors, and used as conductive layers in perovskite solar cells.

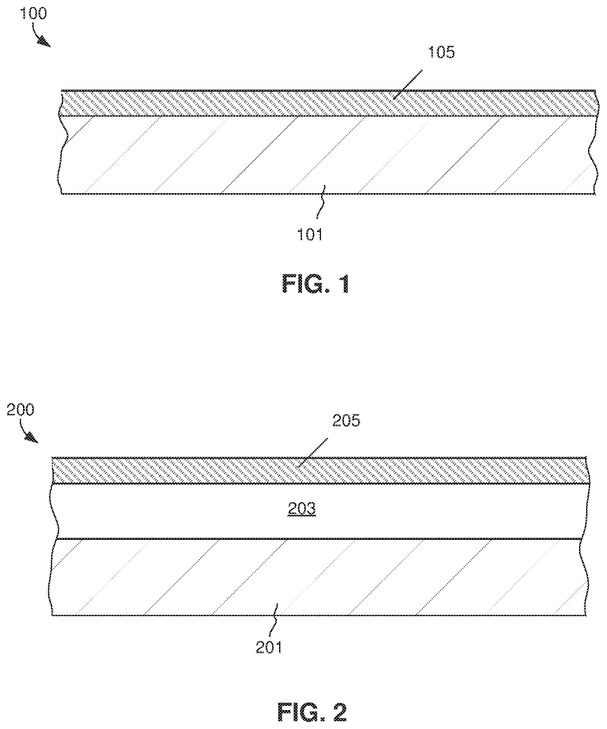

FIG. 1 illustrates a cross-sectional schematic of an example substrate having a metal layer with graphene deposited thereon according to some implementations. The substrate 100 can be any wafer, semiconductor wafer, partially fabricated integrated circuit, printed circuit board, display screen, or other appropriate workpiece. In some implementations, the substrate 100 is a semiconductor substrate such as a silicon (Si) substrate. The substrate 100 can include a metal layer 101 with an exposed metal surface. As discussed below, the metal layer 101 can also be referred to as a temperature sensitive underlayer. In some implementations, the metal layer 101 can include any appropriate metal such as a transition metal. For example, the metal surface 101 can include copper (Cu). A graphene film 105 can be deposited on the metal layer 101.

Depositing a graphene film 105 on the metal layer 101 is typically accomplished at high temperatures. In some instances, the graphene film 105 may be deposited on the metal layer 101 using thermal CVD at temperatures greater than about 800° C. In some instances, the graphene film 105 may be deposited on the metal layer 101 using a plasma-based process at temperatures less than about 800° C. For deposition of graphene film 105 on a layer of cobalt (Co), deposition temperatures using a thermal- or plasma-based process have generally exceeded 550° C. Such temperatures are incompatible with semiconductor processing, such as back-end-of-line (BEOL) semiconductor processing.

In some implementations of the present disclosure, the substrate 100 can include a temperature sensitive underlayer 101. The temperature sensitive underlayer 101 may have a temperature sensitive limit. Above the temperature sensitive limit of the temperature sensitive underlayer 101, the temperature sensitive underlayer 101 melts or is otherwise physically damaged. The temperature sensitive limit may be between about 400° C. and about 700° C. for many materials of the temperature sensitive underlayer 101. Some thermal CVD methods and some conventional plasma-based CVD methods may exceed the temperature sensitive limit of the temperature sensitive underlayer 101. Examples of temperature sensitive underlayers 101 can include metals such as copper, cobalt, and ruthenium (Ru).

FIG. 2 illustrates a cross-sectional schematic of an example substrate having a cobalt layer on a copper layer, with nano-graphene deposited on the cobalt layer according to some implementations. The substrate 200 can be any wafer, semiconductor wafer, partially fabricated integrated circuit, printed circuit board, display screen, or other appropriate workpiece. In some implementations, the substrate 200 is a semiconductor substrate such as a silicon substrate. The substrate 200 can include a first metal layer 201 with a second metal layer 203 deposited thereon. In some implementations, the first metal layer 201 includes copper. In some implementations, the second metal layer 203 includes cobalt. However, it will be understood that the second metal layer 203 may be any appropriate metal, where example metals can include but are not limited to copper, cobalt, ruthenium, molybdenum (Mo), and nickel (Ni). For example, a nano-graphene layer 205 may be deposited on the second metal layer 203.

The nano-graphene layer 205 may be deposited at temperatures less than about 550° C., such as temperatures below about 500° C., below about 450° C., below about 400° C., below about 350° C., or between about 200° C. and about 400° C. The nano-graphene layer 205 may be deposited on the second metal layer 203 such as a cobalt layer using a multi-step process, including a thermal deposition step followed by a plasma treatment step. Deposition of the nano-graphene layer 205 occurs at low temperatures that are compatible with semiconductor processing, and particularly with BEOL semiconductor processing. Where the second metal layer 203 (e.g., cobalt layer) is a temperature sensitive underlayer, the nano-graphene layer 205 is deposited at sufficiently low temperatures that do not melt or otherwise physically damage the temperature sensitive underlayer.

The nano-graphene layer 205 may selectively deposit on the second metal layer 203. The nano-graphene layer 205 deposits on metal surfaces but does not deposit on exposed dielectric or non-metal surfaces. Deposition of the nano-graphene layer 205 using a thermal deposition step and a plasma treatment step as described in the present disclosure can selectively deposit high-quality nano-graphene metal surfaces relative to other non-metal surfaces at low temperatures suitable for semiconductor applications. The high-quality nano-graphene may be used in a wide number of industrial applications.

Allotropes of carbon may be characterized by a ratio of sp2 to sp3 hybridized bonds. Diamond has purely sp3 bonds and graphite/graphene has purely sp2 bonds. Amorphous carbons can have some ratio of sp3 to sp2 hybridized bonds in an amount between diamond and graphite/graphene. Amorphous carbons generally contain a certain degree of disorder or non-crystallinity compared to more ordered structures of diamond and graphene.

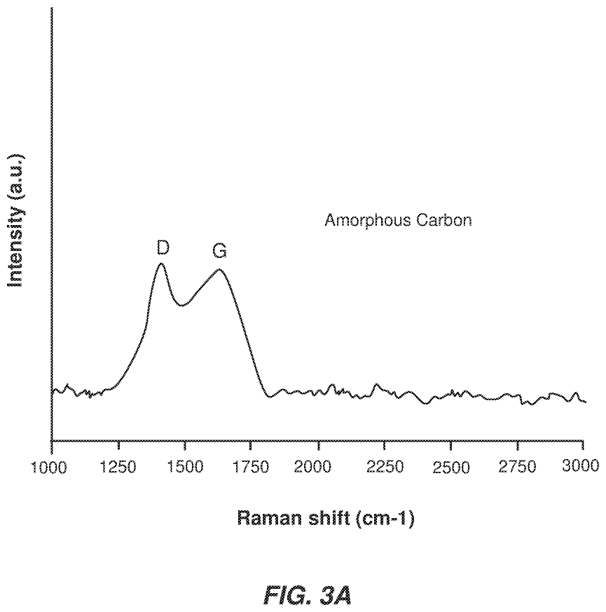

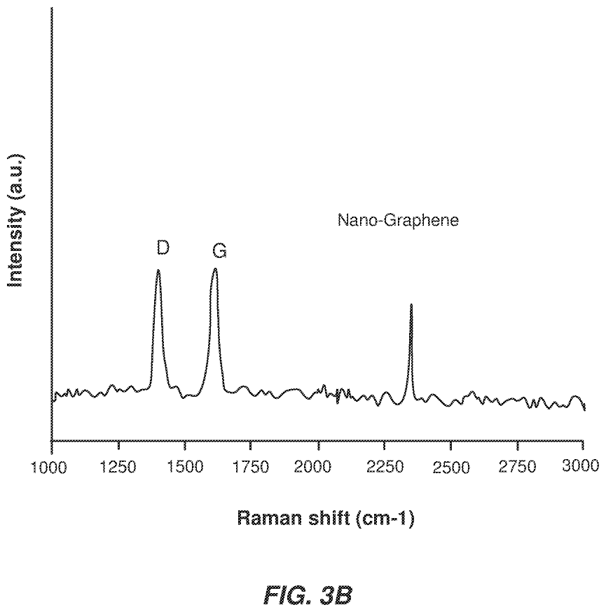

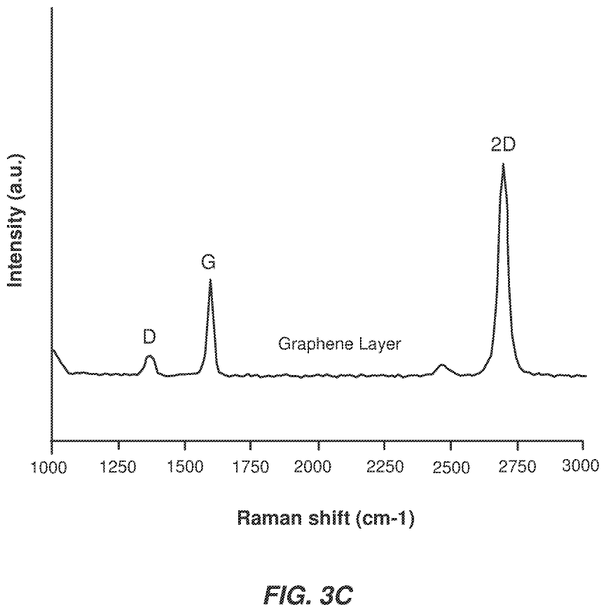

FIG. 3A illustrates a graph showing Raman spectrum of an example amorphous carbon layer according to some implementations. An amorphous carbon film can be characterized in a Raman spectrum by the presence of at least two peaks between around 1000 cm⁻¹ and 1700 cm⁻¹. In particular, the amorphous carbon film can be characterized by the presence of a G peak (G for graphite) at around 1580 cm⁻¹ and a D peak (D for disorder) at around 1380 cm⁻¹. Disordered carbon or amorphous carbon, can be strongly characterized by the presence of the D peak. As disorder increases, the Raman intensity of the D peak usually increases. The higher the Raman intensity, the greater the number of defects. Such defects may include but are not limited to vacancies that signal a lack of graphene, or grain boundaries that otherwise disrupt the infinite planar structure of a graphene film. The G peak may be indicative of graphitic structures or the presence of sp2 hybridized carbon bonding. The D peak and the G peak in amorphous carbon are typically broad as opposed to sharp.

FIG. 3B illustrates a graph showing Raman spectrum of an example nano-graphene layer on a metal layer according to some implementations. A nano-graphene layer can be characterized in a Raman spectrum by at least two sharp peaks between around 1000 cm⁻¹ and 1700 cm⁻¹. The nano-graphene layer can be characterized by the presence of a G peak at around 1580 cm⁻¹ and a D peak at around 1380 cm⁻¹. In contrast to typical amorphous carbon films, the nano-graphene layer can be characterized by sharper peaks. The sharp G peak is representative of crystalline sp2 hybridized carbon bonding of the nano-graphene layer. The sharp D peak is representative of disorder in the form of small crystallite sizes or an abundance of edges in the nano-graphene layer. A typical amorphous carbon film may have one broad peak that is a contribution of D and G peaks. Or, a typical amorphous carbon film may have broader D peaks and G peaks as shown in FIG. 3A than the nano-graphene layer as shown in FIG. 3B. A low-quality nano-graphene layer may have distinct D and G peaks compared to typical amorphous carbon layers, while a high-quality nano-graphene layer may have sharper D and G peaks than the low-quality nano-graphene layer. In other words, the low-quality nano-graphene layer may have

FIG. 3C illustrates a graph showing Raman spectrum of an example graphene layer on a metal layer according to some implementations. A graphene layer can be characterized in a Raman spectrum by at least three peaks between around 1000 cm⁻¹ and 3000 cm⁻¹. A graphene layer has fewer defects and contains more order than a nano-graphene layer. In fact, the graphene layer is characterized as a singular two-dimensional sheet of carbon atoms in a hexagonal lattice. The graphene layer can be characterized by three peaks, including a D peak at around 1380 cm⁻¹, a G peak at around 1580 cm⁻¹, and a 2D peak (secondary D) at around 2680 cm⁻¹. The Raman intensity of the D peak is usually lower for a graphene layer compared to a nano-graphene layer, which is indicative of the removal of defects and/or increased crystallite size. Furthermore, the presence of the G peak is indicative of crystalline sp2 hybridized carbon bonding and the presence of the 2D peak is indicative of a more ordered graphene layer or sheet. Accordingly, the graphene layer of FIG. 3C shows a reduced D peak and an emerging 2D peak compared to the nano-graphene layer of FIG. 3B.

Raman spectroscopy can also be used to determine a number of graphene or nano-graphene layers. In some implementations, the ratio of the intensity of the 2D peak to the intensity of the G peak (I_{2D}/I_{G}) can correspond to the number of graphene or nano-graphene layers. Specifically, if the ratio of I_{2D}/I_{G} is greater than 2, then a deposited film corresponds to single layer graphene. If the ratio of I_{2D}/I_{G} is slightly greater than 1 or slightly less than 1, then a deposited film may correspond to bilayer graphene or few layer graphene, respectively.

Raman spectroscopy can also be used to determine the grain size and type of crystal in the graphene or nano-graphene structure. In some implementations, the ratio of the intensity of the G peak to the intensity of the D peak (I_{G}/I_{D}) can correspond to grain size. As the ratio increases, this is an indication of increasing crystal grain size. Additionally, as the ratio decreases, this is an indication of increasing number of defects that may otherwise disrupt the planar structure of graphene.

In some implementations, a nano-graphene layer deposited on a metal surface has a thickness equal to or less than about 5 nm, equal to or less than about 3 nm, equal to or less than about 1 nm, or equal to or less than about 0.5 nm. The thickness of the nano-graphene layer can depend on the metal surface on which it is deposited. For example, the nano-graphene layer may be a monolayer or a few monolayers thick when deposited on copper, and so the thickness may be less than about 1 nm. In another example, the nano-graphene layer may be a few nanometers thick (e.g., about 2-3 nm) when deposited on other metals such as cobalt.

In the present disclosure, a high-quality nano-graphene layer is deposited on a metal layer of a substrate at low temperatures using a two-step process of thermal deposition and plasma treatment. Low temperatures may be considered to be less than about 500° C., equal to or less than about 400° C., or between about 200° C. and about 400° C. A nano-graphene layer is initially deposited by introducing hydrocarbon precursors having alkene or alkyne groups to adsorb on the metal layer, where the metal layer interacts with the adsorbed hydrocarbon precursors at a temperature between about 200° C. and about 400° C. to produce the nano-graphene layer. The nano-graphene layer is treated by plasma such as remote plasma to form high-quality nano-graphene on the metal layer. In some instances, the metal layer includes cobalt.

Alternatively, a high-quality nano-graphene layer is deposited on a metal layer at low temperatures using a two-step process of plasma deposition and plasma treatment in the present disclosure. The nano-graphene layer is initially deposited by generating carbon-containing radicals from hydrocarbon precursors having alkene or alkyne groups in a remote plasma source, and flowing the carbon-containing radicals to the metal layer of a substrate. The nano-graphene layer may be subsequently treated by remote plasma without flowing carbon-containing radicals to form the high-quality nano-graphene layer. In some implementations, the metal layer includes cobalt.

As used herein, the term “remote” in literature generally refers to the remoteness of the substrate from the plasma. As used herein, a “remote plasma” is a plasma in which plasma generation occurs at a location that is remote from the substrate.

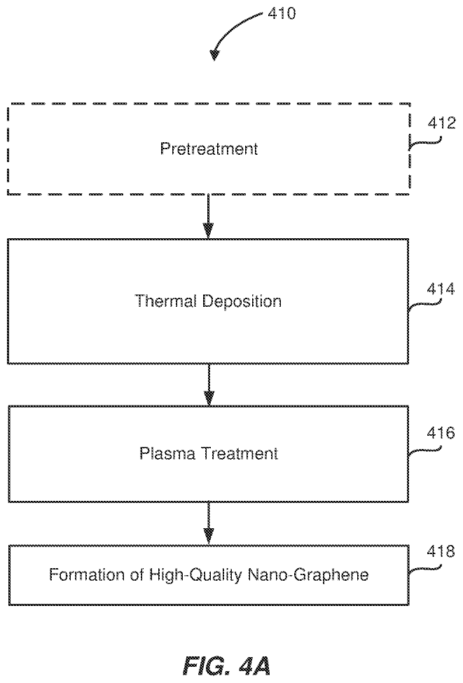

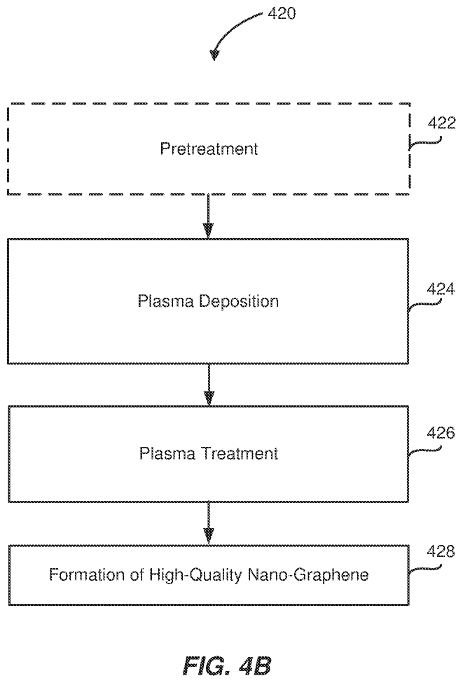

FIG. 4A illustrates a flow chart of an example method of a deposition and treatment process for depositing nano-graphene on a metal layer according to some implementations. A process 410 may be illustrative of a two-step process of thermal deposition followed by plasma treatment. The process 410 may be carried out at low temperatures compatible for BEOL semiconductor processing, which can be less than about 500° C. At block 412 of the process 410, a substrate having a metal layer is pretreated. The pretreatment may entail removal of impurities and/or removal of metal oxides from the surface of the substrate. At block 414 of the process 410, nano-graphene may be deposited on the metal layer by thermal deposition. Hydrocarbon precursors may be flowed to the metal layer where the metal layer acts as a catalyst for dehydrogenating the hydrocarbon precursors to form nano-graphene on the metal layer. At block 416, the substrate is exposed to plasma to treat the nano-graphene. The treatment may be a remote plasma treatment that supplies energy for rearranging and reordering the nano-graphene. At block 418 of the process 410, a high-quality nano-graphene layer is formed after plasma treatment of the nano-graphene on the metal layer.

FIG. 4B illustrates a flow chart of an example method of a deposition and treatment process for depositing nano-graphene on a metal layer according to some other implementations. A process 420 may be illustrative of a two-step process of plasma deposition followed by plasma treatment. The process 420 may be carried out at low temperatures compatible for BEOL semiconductor processing, which can be less than about 500° C. At block 422 of the process 420, a substrate having a metal layer is pretreated. The pretreatment may entail removal of impurities and/or removal of metal oxides from the surface of the substrate. At block 424 of the process 420, nano-graphene may be deposited on the metal layer by plasma deposition. Carbon-containing radicals may be generated from a source gas of hydrocarbon precursors in a remote plasma source. The metal layer may be exposed to remote plasma comprising the carbon-containing radicals, where the carbon-containing radicals interact with the metal layer to form nano-graphene on the metal layer. At block 426 of the process 420, the substrate is exposed to plasma without carbon-containing radicals to treat the nano-graphene. The treatment may be a remote plasma treatment that supplies energy for rearranging and reordering the nano-graphene. At block 428 of the process 420, a high-quality nano-graphene layer is formed after plasma treatment of the nano-graphene on the metal layer.

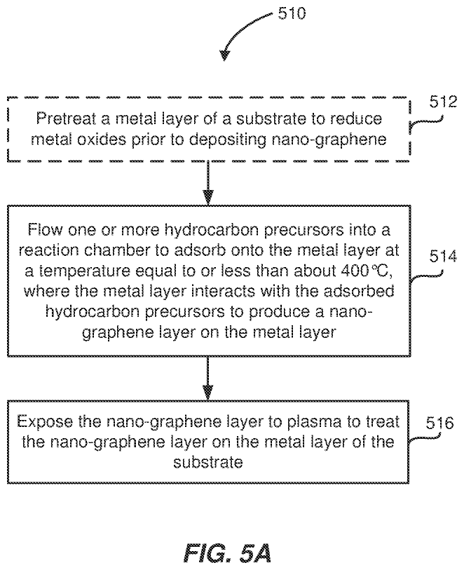

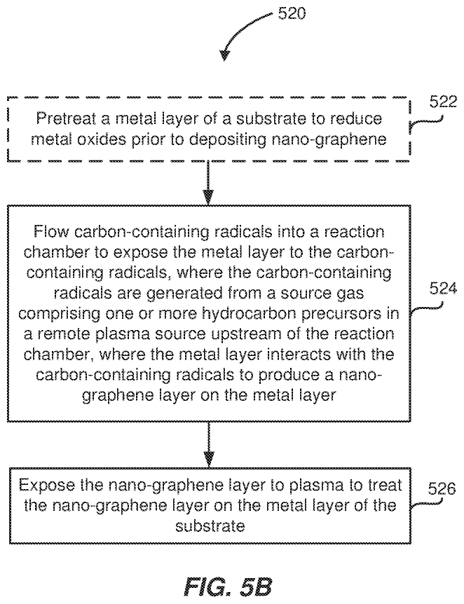

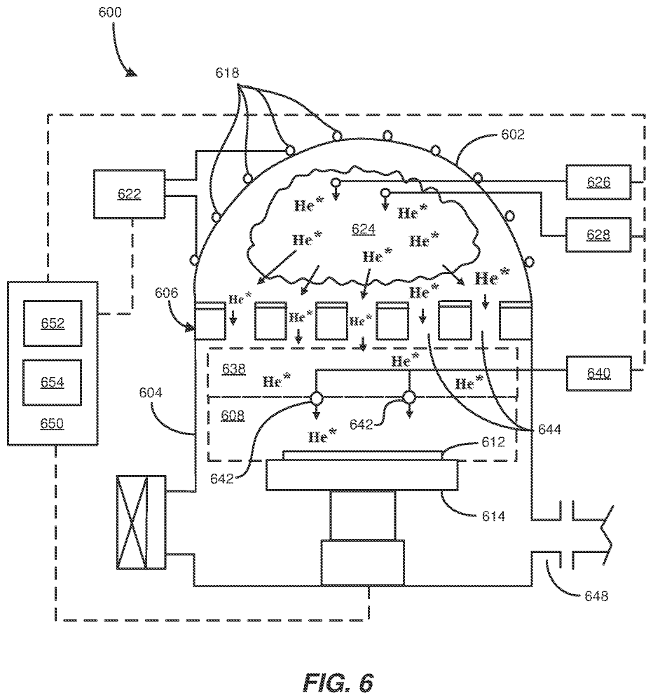

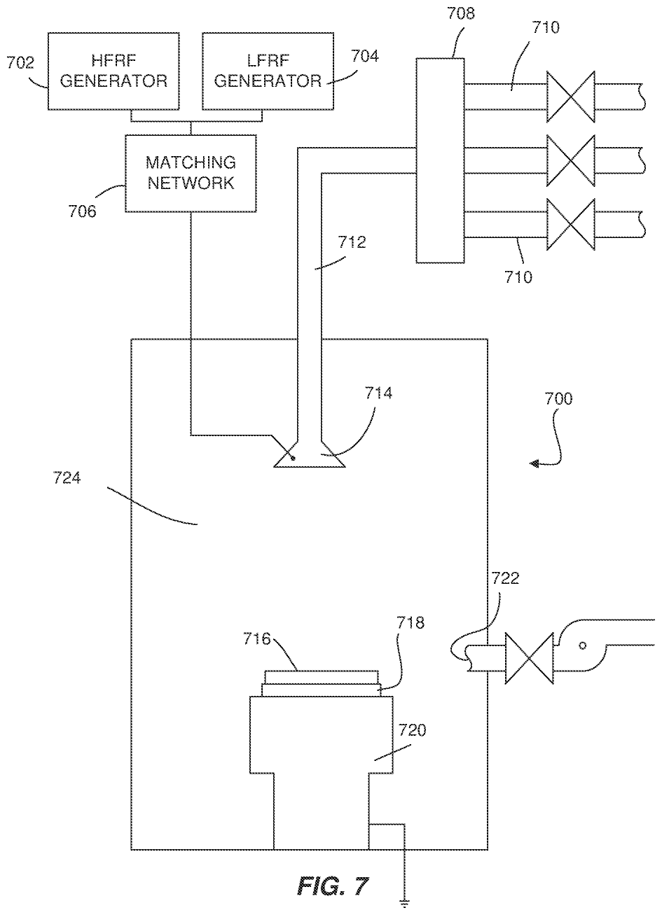

FIG. 5A illustrates a flow diagram of an example method for depositing nano-graphene on a metal surface according to some implementations. The operations of a process 510 may be performed in different orders and/or with different, fewer, or additional operations. One or more operations of the process 510 may be performed using a processing apparatus shown in FIG. 6 or 7. In some implementations, the operations of the process 510 may be implemented, at least in part, according to software stored in one or more non-transitory computer readable media.

At block 512 or the process 510, a metal layer of a substrate is optionally pretreated to reduce metal oxides prior to depositing nano-graphene. The substrate may be supported on a substrate support or pedestal in the reaction chamber. The substrate can be any wafer, semiconductor wafer, partially fabricated integrated circuit, printed circuit board, display screen, or other appropriate workpiece. In some implementations, the substrate may include a metal layer that includes a metal such as copper (Cu), nickel (Ni) molybdenum (Mo), cobalt (Co), and ruthenium (Ru). In one example, the metal layer includes cobalt. In another example, the metal layer includes ruthenium. The metal layer may be relatively thin, where a thickness of the metal layer may be between about 5 Å and about 50 Å or between about 10 Å and about 20 Å.

Deposition of nano-graphene on the metal layer may depend on the smoothness and purity of the surface of the metal layer on which nano-graphene is grown. Surface preparation techniques may be applied on the surface of the metal layer to polish the substrate and remove impurities. Polishing the substrate may be performed by a light etch in some implementations. Removal of impurities may be performed by a chemical treatment that removes, for example, metal oxides. Removal of impurities may additionally or alternatively involve removal of residues or contaminants from chemical mechanical planarization (CMP) processes.

In some implementations, treating the metal layer of the substrate can include exposing the surface of the metal layer to a plasma of a reducing gas species. Thus, pretreatment of the metal layer can at least include reduction of metal oxides by exposure to plasma. In some implementations, the plasma can include ions and radicals of reducing gas species. The ions and/or radicals of the reducing gas species react with metal oxides under conditions that convert the metal oxides to metal. Reducing gas species can include hydrogen-containing gases such as, for example, hydrogen (H₂), ammonia (NH₃), hydrazine (N₂H₄), or combinations thereof. Other possible reducing gas species can include carbon monoxide (CO), diborane (B₂H₆), sulfites, phosphites, and hydrocarbons. In some cases, the surface of the metal layer may be pretreated by an H₂ plasma, NH₃ plasma, or H₂/NH₃ plasma. The plasma may be a direct (in-situ) plasma or remote plasma. In some implementations, exposing the surface of the metal layer to the plasma of the reducing gas species includes exposing the metal surface to a remote hydrogen plasma. Where pretreatment of the substrate involves exposure to remote plasma of reducing gas species, the pretreatment may be carried out in a remote plasma processing apparatus, an example of which is described with reference to FIG. 6.

By way of an example, pretreatment of the metal layer for reducing metal oxides can include exposure to plasma generated from a gas mixture of hydrogen and helium. The gas mixture may optionally further include oxygen. Hydrogen may be supplied to a plasma source (e.g., remote plasma source) at a flow rate between about 500 sccm and about 5000 sccm. The hydrogen acts as a reducing gas species. The reducing gas species may be flowed with a carrier gas or inert gas such as helium (He), neon (Ne), argon (Ar), krypton (Kr), or xenon (Xe). Helium may be supplied to the plasma source at a flow rate between about 1000 sccm and about 36000 sccm. In some cases, a concentration of helium may be at least two times greater than a concentration of hydrogen. However, it will be understood that the concentration of helium may not be twice the concentration of hydrogen, but may even be equal to or less than the concentration of hydrogen. Additional gases may be flowed with the reducing gas species. Oxygen may be optionally supplied at a flow rate between about 1 sccm and about 40 sccm. The oxygen may serve to promote dissociation of hydrogen gas into hydrogen radicals in the plasma source. A concentration of oxygen may be substantially less than a concentration of hydrogen. The concentration of oxygen may be substantially less than a concentration of helium. The concentration of oxygen may be at least five times less or at least ten times less than the concentration of hydrogen. The concentration of oxygen may be at least five times less or at least ten times less than the concentration of helium. Because the oxygen may be provided in small amounts, little to no oxygen reaches the substrate during pretreatment because the oxygen is largely consumed in the plasma source. In some implementations, a pressure in the reaction chamber may be between about 0.5 Torr and about 10 Torr or between about 1 Torr and about 5 Torr. In some implementations, an RF power supplied for plasma generation in the remote plasma source is between about 300 W and about 5000 W or between about 500 W and about 3000 W.

In some implementations, pretreating the surface of the metal layer includes exposing the surface of the metal layer to a cyano-based radical species (e.g., CN*). Cyano-based radical species may be produced from a gas mixture containing a precursor having a carbon-nitrogen (CN) bond such as hydrogen cyanide (HCN), hydrogen isocyanide (HNC), and protonated hydrogen cyanide (HCNH⁺). Cyano-based radical species may perform a light etch for smoothing the metal surface prior to nano-graphene growth. Exposing the surface of the metal layer to the cyano-based radical species can occur before, after, or in lieu of exposing the surface of the metal layer to plasma of the reducing gas species.

In some implementations, pretreating the surface of the metal layer includes exposing the surface of the metal layer to thermal forming gas anneal. The forming gas includes a mixture of hydrogen and nitrogen gas. The thermal forming gas anneal may expose metal oxides to temperatures higher than about 150° C. to reduce the metal oxides to metal.

At block 514 of the process 510, one or more hydrocarbon precursors are flowed into a reaction chamber to adsorb onto the metal layer at a temperature equal to or less than about 400° C. The metal layer interacts with the adsorbed hydrocarbon precursors to produce a nano-graphene layer on the metal layer. Accordingly, nano-graphene may be deposited on the metal layer in a thermal deposition process without any assistance of plasma. Instead, the nano-graphene may be deposited at low temperatures compatible with semiconductor manufacturing processes. In some implementations, the temperature is between about 200° C. and about 400° C.

Without being limited by any theory, the hydrocarbon precursors react with the metal layer so that the hydrocarbon precursors dehydrogenate. The metal layer acts as a catalyst for breaking down the hydrocarbon precursors so that hydrogen atoms are selectively removed and carbon atoms are released. Hydrogen atoms diffuse out as a gas. The temperature at the substrate surface may be sufficient to catalyze dehydrogenation and nano-graphene growth on the metal layer. In cases where the carbon solubility of the metal is high, the carbon atoms may diffuse into the metal layer. Example metals with high carbon solubility include cobalt and nickel. The carbon atoms may out-diffuse to the surface of the metal layer and initiate nucleation on the surface of the metal layer. Out-diffusion may be enhanced by a relatively thin metal layer, where a thickness of the metal layer may be less than about 100 Å or less than about 50 Å. The surface of the metal layer promotes nucleation and growth so that carbon atoms are arranged and segregated at the metallization surface. The segregated carbon atoms at the metallization surface deposit nano-graphene on the metal layer.

The one or more hydrocarbon precursors are delivered in the gas phase. Each of the one or more hydrocarbon precursors may include an alkene or alkyne group. This means that the hydrocarbon precursors include one or more unsaturated carbon bonds, such as one or more carbon-to-carbon double bonds and/or carbon-to-carbon triple bonds. Examples of hydrocarbon precursors having alkene or alkyne groups include but are not limited to acetylene (C₂H₂), ethylene (C₂H₄), propylene (C₃H₆), butene (C₄Ha), pentadiene (e.g., 1,4 pentadiene (C₅H₈)), hexene (C₆H₁₂), propyne (C₃H₄), butyne (C₄H₆), or pentyne (C₅H₈). Some hydrocarbon precursors may be aromatic hydrocarbons such as toluene (C₇H₈) and benzene (C₆H₆).

In some instances, the hydrocarbon precursor includes only C and H atoms. The hydrocarbon compound can be CₓH_{y}, wherein x is an integer from 1 to 10 and wherein y is an integer from 2 to 24. Some other non-limiting hydrocarbons can include propadiene (C₃H₄), allene (C₃H₄), 1,3-butadiene (C₄H₆), 1,2-butadiene (C₄H₆), isoprene (C₅H₈), piperylene (C₅H₈), dimethylbutadiene (C₆H₁₀), 1,5-hexadiene (C₆H₁₀), 1,7-octadiene (C₈H₁₄), and the like. Some hydrocarbons may be cyclic hydrocarbons such as cyclopropene (C₃H₄), cyclobutene (C₄H₆), cyclohexene (C₆H₁₀), and norbornene (C₇H₁₀).

Alkenes or alkynes may be linear, branched, and/or cyclic. In one embodiment, the alkene or alkyne is linear or branched. Such linear and branched alkenes can include one, two, three, four, or more carbon-carbon double bonds. Such linear and branched alkynes can additionally or alternatively include one, two, three, four, or more carbon-carbon triple bonds. Non-limiting precursors can include C₂₋₁₀ alkenes and C₂₋₁₀ alkynes. In other embodiments, the alkene includes a formula of R¹R²C═CR³R⁴, in which each of R¹, R², R³, and R⁴ is, independently, H, optionally substituted alkyl (e.g., substituted C₁₋₈ alkyl), or optionally substituted alkenyl (e.g., substituted C₂₋₈ alkenyl). In yet other embodiments, the alkyne includes a formula of R¹C≡CR², in which each of R¹ and R² is, independently, H, optionally substituted alkyl (e.g., substituted C₁₋₈ alkyl), optionally substituted alkenyl (e.g., substituted C₂₋₈ alkenyl), or optionally substituted alkynyl (e.g., substituted C₂₋₈ alkynyl).

In particular embodiments, the precursor is an alkene having one or more double bonds or an alkyne having one or more triple bonds, in which the alkene or the alkyne can be linear or cyclic. Example alkenes include ethene, propene, 1-butene, 1-pentene, 1-hexene, 1-heptene, 1-octene, and 1-nonene, as well as dienes of any of these and positional isomers if available, in which the location of the double bond is changed (e.g., a positional isomer of 1-butene could be 2-butene, etc.). Example alkynes include ethyne, propyne, 1-butyne, 1-pentyne, 1-hexyne, 1-heptyne, 1-octyne, and 1-nonyne, as well as positional isomers if available, in which the location of the triple bond is changed (e.g., a positional isomer of 1-butyne could be 2-butyne, etc.).

Yet other examples of hydrocarbon precursors can include a cycloaliphatic compound (e.g., C₃₋₁₂ cycloalkene such as cyclohexene or norbornene, or C₃₋₁₂ cycloalkyne) or an aromatic compound (e.g., benzene, toluene, naphthalene, phenanthrene, as well as other polycyclic forms thereof). The hydrocarbon precursor can include saturated bonds (single bonds, e.g., C—C bonds or C—H bonds) and/or unsaturated bonds (double or triple bonds, e.g., C═C or C≡C bonds). In some embodiments, a cyclic alkene or cyclic alkyne is a cycloaliphatic compound, as described herein, having one or more carbon-carbon double bonds and/or triple bonds (i.e., C═C and/or C≡C bonds). In other embodiments, the hydrocarbon precursor is an unsaturated, cyclic hydrocarbon (e.g., cyclopentene, cyclohexene, cycloheptene, etc.).

Hydrocarbon precursors with alkene or alkyne groups may dehydrogenate at the metal layer at a temperature between about 200° C. and about 400° C. to deposit a nano-graphene layer. The metal layer such as a copper, nickel, molybdenum, cobalt, or ruthenium layer may serve as a catalyst for breaking down the hydrocarbon precursors and promoting nucleation of nano-graphene to form the nano-graphene layer. The nano-graphene layer is initially formed on the metal layer without generation or application of plasma. In some embodiments, the nano-graphene layer is selectively deposited on the metal layer relative to dielectric surfaces or other non-metal surfaces of the substrate. In some implementations, the nano-graphene layer may be a low-quality nano-graphene layer. The low-quality nano-graphene layer may be characterized by D and G peaks in a Raman spectrum. A 2D peak may be negligible or missing in the Raman spectrum.

In some implementations, the one or more hydrocarbon precursors are delivered with other species, notably carrier gas. Upstream from the deposition reaction surface, the one or more hydrocarbon precursors can be mixed with an inert carrier gas. Example inert carrier gases include, but are not limited to helium, neon, argon, krypton, and xenon. In some implementations, the one or more hydrocarbon precursors are delivered as a mixture of multiple hydrocarbon precursors. The multiple hydrocarbon precursors may be present in equimolar or relatively similar proportions as appropriate to form the primary backbone or matrix in the resulting nano-graphene. In other implementations, the relative amounts of the multiple hydrocarbon precursors are substantially skewed from equimolarity.

In some implementations, the one or more hydrocarbon precursors are delivered with other species, such as hydrogen (H₂) into the reaction chamber. Upstream from the deposition reaction surface, the one or more hydrocarbon precursors can be mixed with hydrogen. The hydrogen may interact with the metal layer such as a cobalt layer where the nano-graphene layer is deposited. Without being limited by any theory, the presence of hydrogen may increase a grain size of the nano-graphene. In some alternative implementations, the one or more hydrocarbon precursors are delivered with oxygen (O₂) into the reaction chamber.

By way of an example, one or more hydrocarbon precursors may be delivered to the substrate in a mixture with helium and hydrogen. Hydrocarbon precursors may be supplied to the reaction chamber at a flow rate between about 100 sccm and about 5000 sccm or between about 200 sccm and about 2500 sccm. The hydrocarbon precursors may be flowed with an inert gas such as helium. Helium may be supplied to the reaction chamber at a flow rate between about 1000 sccm and about 36000 sccm. In some cases, a concentration of helium may be at least two times greater than a concentration of the one or more hydrocarbon precursors. Additional gases may be flowed with the one or more hydrocarbon precursors. Hydrogen may be optionally supplied at a flow rate between about 1000 sccm and about 9000 sccm. A concentration of hydrogen may be greater than a concentration of the one or more hydrocarbon precursors. In some embodiments, a pressure in the reaction chamber may be between about 0.5 Torr and about 20 Torr or between about 1 Torr and about 8 Torr.

The one or more hydrocarbon precursors may flow into the reaction chamber through one or more gas ports fluidly coupled to the reaction chamber. In some embodiments, the formation of the nano-graphene layer by thermal deposition using the one or more hydrocarbon precursors is performed using a remote plasma processing apparatus, an example of which is described with reference to FIG. 6. Accordingly, the reaction chamber for performing pretreatment at block 512 may be the same as performing deposition at block 514. In fact, the reaction chamber for performing deposition at block 514 may be the same as performing plasma treatment at block 516. Though plasma is not generated or applied during deposition at block 514, the remote plasma processing apparatus may be equipped with one or more heaters for maintaining a substrate temperature equal to or less than about 400° C., or between about 200° C. and about 400° C. The one or more heaters may be incorporated in the substrate support or wafer pedestal of the reaction chamber. The one or more gas ports for delivering the hydrocarbon precursors may be positioned downstream from a remote plasma source of the remote plasma processing apparatus. By performing thermal deposition of the nano-graphene layer at block 514 in the same reaction chamber as pretreatment at block 512 and/or plasma treatment at block 516, the process 510 increases throughput, reduces processing costs, eliminates substrate transfers, and avoids vacuum breaks that occur between substrate transfers that may otherwise expose the substrate to unwanted materials, atmosphere, and moisture. In some other implementations, the thermal deposition of the nano-graphene layer at block 514 may be performed in a different reaction chamber but within the same tool as pretreatment at block 512 and/or plasma treatment at block 516. In some other implementations, the thermal deposition of the nano-graphene layer at block 514 may be performed in a different reaction chamber of a different tool than pretreatment at block 512 and/or plasma treatment at block 516.

In some embodiments, the nano-graphene layer may be deposited by thermal deposition for a duration between about 1 second and about 200 seconds, between about 2 seconds and about 100 seconds, or between about 3 seconds and about 50 seconds. Thermal deposition may be shorter when repeated in alternating cycles between thermal deposition at block 514 and plasma treatment at block 516. Or, thermal deposition may be longer when thermal deposition at block 514 and plasma treatment at block 516 are not repeated.

At block 516 of the process 510, the nano-graphene layer is exposed to plasma to treat the nano-graphene layer on the metal layer of the substrate. The plasma treatment of the nano-graphene layer may produce a high-quality nano-graphene layer. The plasma treatment may occur at a temperature equal to or less than about 400° C., such as between about 200° C. and about 400° C. During plasma treatment, flow of the one or more hydrocarbon precursors may be turned off. In some embodiments, the exposing the nano-graphene layer to plasma may comprise exposing the nano-graphene layer to remote plasma.

The plasma may be an inert gas plasma. The inert gas plasma may be free or substantially free of carbon-containing gases. An inert gas such as helium, neon, argon, krypton, or xenon may be supplied to a plasma source (e.g., remote plasma source). For instance, the inert gas plasma may be a helium plasma. The plasma source may generate radicals of the inert gas. Without being limited by any theory, the radicals of the inert gas may bombard the nano-graphene layer, or impart sufficient thermal energy to the nano-graphene layer, to rearrange carbon atoms to provide a more ordered nano-graphene structure with fewer defects. The radicals of the inert gas may break weak bonds and/or supply heat energy (in addition to the heat energy from the wafer pedestal) for reordering carbon atoms in the nano-graphene layer. Exposure to the inert gas plasma may restructure the nano-graphene layer to provide a high-quality nano-graphene layer. In some embodiments, the inert gas plasma may be a remote inert gas plasma so as to provide a gentle and indirect plasma treatment that avoids etching or otherwise damaging the nano-graphene layer.

The nano-graphene layer after plasma treatment may be characterized by even sharper D and G peaks in a Raman spectrum compared to the nano-graphene layer prior to plasma treatment.

In some embodiments, inert gas may be flowed with other species such as hydrogen. Hydrogen may be mixed with inert gas in the plasma source. For example, hydrogen radicals may be generated with helium radicals in a remote plasma source and flowed towards the substrate in the reaction chamber, where the reaction chamber is downstream from the remote plasma source. Thus, exposing the nano-graphene layer to plasma can include exposing the nano-graphene layer to remote hydrogen-helium plasma.

In some embodiments, inert gas may be flowed with other species such as oxygen. Oxygen may be mixed with inert gas in the plasma source, or oxygen may be mixed with hydrogen and inert gas in the plasma source. For instance, oxygen radicals may be generated with helium radicals in a remote plasma source and flowed towards the substrate in the reaction chamber, where the reaction chamber is downstream from the remote plasma source. Accordingly, exposing the nano-graphene layer to plasma can include exposing the nano-graphene layer to remote oxygen-helium plasma.

By way of an example, helium may be delivered to the plasma source at a flow rate between about 1000 sccm and about 36000 sccm. In some implementations, hydrogen may be flowed simultaneously with helium and delivered to the plasma source at a flow rate between about 1000 sccm and about 9000 sccm. In some implementations, oxygen may be flowed simultaneously with helium and delivered to the plasma source at a flow rate between about 1 sccm and about 40 sccm. A concentration of helium may be at least two times greater than a concentration of hydrogen and at least five times or at least ten times greater than a concentration of oxygen. In some implementations, a pressure in the reaction chamber is between about 0.5 Torr and about 20 Torr or between about 1 Torr and about 8 Torr. In some implementations, an RF power supplied for plasma generation in the remote plasma source is between about 300 W and about 5000 W or between about 500 W and about 3000 W.

The nano-graphene layer may be treated by plasma in a reaction chamber of a plasma processing apparatus. The plasma processing apparatus may generate plasma in-situ or generate plasma remotely. In some embodiments, the nano-graphene layer may be treated by plasma in a remote plasma processing apparatus, an example of which is described with reference to FIG. 6. Radicals of inert gas may be generated in a remote plasma source upstream from the reaction chamber and delivered to the reaction chamber via a showerhead fluidly coupled to the remote plasma source. In some embodiments, the reaction chamber for performing plasma treatment at block 516 may be the same as performing deposition at block 514. In some embodiments, the reaction chamber for performing plasma treatment at block 516 may be the same as performing pretreatment at block 512. The remote plasma processing apparatus may be equipped with one or more heaters for maintaining a substrate temperature equal to or less than about 400° C., such as between about 200° C. and about 400° C.

In some embodiments, the nano-graphene layer may be treated by plasma for a duration between about 1 second and about 200 seconds, between about 2 seconds and about 100 seconds, or between about 3 seconds and about 50 seconds. Thermal deposition and plasma exposure may be shorter but repeated in alternating cycles between thermal deposition at block 514 and plasma treatment at block 516. Operations of thermal deposition at block 514 and plasma treatment at block 516 may be repeated to form a desired thickness of the nano-graphene layer. In some implementations, the thickness of the nano-graphene layer is equal to or less than about 10 nm, equal to or less than about 5 nm, equal to or less than about 3 nm, or equal to or less than about 1 nm. Alternatively, thermal deposition and plasma exposure may be longer without repeating operations of thermal deposition at block 514 and plasma treatment at block 516.

FIG. 5B illustrates a flow diagram of an example method for depositing nano-graphene on a metal surface according to some other implementations. The operations of a process 520 may be performed in different orders and/or with different, fewer, or additional operations. One or more operations of the process 520 may be performed using a processing apparatus shown in FIG. 6 or 7. In some implementations, the operations of the process 520 may be implemented, at least in part, according to software stored in one or more non-transitory computer readable media.

At block 522 of the process 520, a metal layer of a substrate is optionally pretreated to reduce metal oxides prior to depositing nano-graphene. Aspects of the pretreatment at block 522 may be identical to the pretreatment at block 512 of the process 510. Accordingly, the description of surface preparation of the metal layer of the substrate at block 512 of the process 510, which may involve exposure to plasma of reducing gas species, may apply to pretreatment at block 522 of the process 520.

At block 524 of the process 520, carbon-containing radicals are flowed into a reaction chamber to expose the metal layer to the carbon-containing radicals, where the carbon-containing radicals are generated from a source gas comprising one or more hydrocarbon precursors in a remote plasma source upstream of the reaction chamber. The metal layer interacts with the carbon-containing radicals to produce a nano-graphene layer on the metal layer. The metal layer may include copper, nickel, molybdenum, cobalt, or ruthenium. For example, the metal layer can include cobalt. The carbon-containing precursors adsorb onto the metal layer at a temperature equal to or less than about 400° C., such as between about 200° C. and about 400° C. The metal layer interacts with the adsorbed carbon-containing radicals to produce a nano-graphene layer on the metal layer. Accordingly, nano-graphene may be deposited on the metal layer in an indirect plasma process at low temperatures.

The carbon-containing radicals may include activated alkanes, activated alkenes, or activated alkynes in an environment adjacent to the substrate. Such activated carbon-based molecules may have active sites that promote bonding and cross-linking to form carbon-to-carbon bonds. Without being limited by any theory, the metal layer acts as a catalyst for dehydrogenating the carbon-containing radicals so that hydrogen atoms are selectively removed and carbon atoms are released. Hydrogen atoms may diffuse out as a gas. The thermal energy at the substrate surface may assist in dehydrogenation and nano-graphene growth on the metal layer. In cases where the carbon solubility of the metal is high, the carbon atoms may diffuse into the metal layer. Example metals with high carbon solubility include cobalt and nickel. The carbon atoms may out-diffuse to the surface of the metal layer and initiate nucleation on the surface of the metal layer. Out-diffusion may be enhanced by a relatively thin metal layer, where a thickness of the metal layer may be less than about 100 Å or less than about 50 Å. The surface of the metal layer promotes nucleation and growth so that carbon atoms are arranged and segregated at the metallization surface. The segregated carbon atoms at the metallization surface deposit nano-graphene on the metal layer.

The carbon-containing radicals are delivered in the gas phase. Each of the one or more hydrocarbon precursors may include an alkene or alkyne group. This means that the hydrocarbon precursors include one or more unsaturated carbon bonds, such as one or more carbon-to-carbon double bonds and/or carbon-to-carbon triple bonds. Examples of hydrocarbon precursors having alkene or alkyne groups include but are not limited to acetylene, ethylene, propylene, butene, pentadiene (e.g., 1,4 pentadiene), hexene, propyne, butyne, or pentyne. Some hydrocarbon precursors may be aromatic hydrocarbons such as toluene (C₇H₈) and benzene (C₆H₆).

In some instances, the hydrocarbon precursor includes only C and H atoms. The hydrocarbon compound can be CₓH_{y}, wherein x is an integer from 1 to 10 and wherein y is an integer from 2 to 24. Some other non-limiting hydrocarbons can include propadiene, allene, 1,3-butadiene, 1,2-butadiene, isoprene, piperylene, dimethylbutadiene, 1,5-hexadiene, 1,7-octadiene, and the like. Some hydrocarbons may be cyclic hydrocarbons such as cyclopropene, cyclobutene, cyclohexene, and norbornene.

Alkenes or alkynes may be linear, branched, and/or cyclic. In one embodiment, the alkene or alkyne is linear or branched. Such linear and branched alkenes can include one, two, three, four, or more carbon-carbon double bonds. Such linear and branched alkynes can additionally or alternatively include one, two, three, four, or more carbon-carbon triple bonds. Non-limiting precursors can include C₂₋₁₀ alkenes and C₂₋₁₀ alkynes. In other embodiments, the alkene includes a formula of R¹R²C═CR³R⁴, in which each of R¹, R², R³, and R⁴ is, independently, H, optionally substituted alkyl (e.g., substituted C₁₋₈ alkyl), or optionally substituted alkenyl (e.g., substituted C₂₋₈ alkenyl). In yet other embodiments, the alkyne includes a formula of R¹C≡CR², in which each of R¹ and R² is, independently, H, optionally substituted alkyl (e.g., substituted C₁₋₈ alkyl), optionally substituted alkenyl (e.g., substituted C₂₋₈ alkenyl), or optionally substituted alkynyl (e.g., substituted C₂₋₈ alkynyl).

In particular embodiments, the precursor is an alkene having one or more double bonds or an alkyne having one or more triple bonds, in which the alkene or the alkyne can be linear or cyclic. Example alkenes include ethene, propene, 1-butene, 1-pentene, 1-hexene, 1-heptene, 1-octene, and 1-nonene, as well as dienes of any of these and positional isomers if available, in which the location of the double bond is changed (e.g., a positional isomer of 1-butene could be 2-butene, etc.). Example alkynes include ethyne, propyne, 1-butyne, 1-pentyne, 1-hexyne, 1-heptyne, 1-octyne, and 1-nonyne, as well as positional isomers if available, in which the location of the triple bond is changed (e.g., a positional isomer of 1-butyne could be 2-butyne, etc.).

Yet other examples of hydrocarbon precursors can include a cycloaliphatic compound (e.g., C₃₋₁₂ cycloalkene such as cyclohexene or norbornene, or C₃₋₁₂ cycloalkyne) or an aromatic compound (e.g., benzene, toluene, naphthalene, phenanthrene, as well as other polycyclic forms thereof). The hydrocarbon precursor can include saturated bonds (single bonds, e.g., C—C bonds or C—H bonds) and/or unsaturated bonds (double or triple bonds, e.g., C═C or C≡C bonds). In some embodiments, a cyclic alkene or cyclic alkyne is a cycloaliphatic compound, as described herein, having one or more carbon-carbon double bonds and/or triple bonds (i.e., C═C and/or C≡C bonds). In other embodiments, the hydrocarbon precursor is an unsaturated, cyclic hydrocarbon (e.g., cyclopentene, cyclohexene, cycloheptene, etc.).

In some implementations, the one or more hydrocarbon precursors are delivered as a mixture of multiple hydrocarbon precursors. The multiple hydrocarbon precursors may be present in equimolar or relatively similar proportions as appropriate to form the primary backbone or matrix in the resulting nano-graphene. In other implementations, the relative amounts of the multiple hydrocarbon precursors are substantially skewed from equimolarity.

The carbon-containing radicals may be catalyzed by the metal layer at a temperature equal to or less than about 400° C., such as between about 200° C. and about 400° C. to deposit a nano-graphene layer. The metal layer such as a copper, nickel, molybdenum, cobalt, or ruthenium layer may serve as a catalyst for breaking down the carbon-containing radicals and promoting nucleation of nano-graphene to form the nano-graphene layer. The nano-graphene layer is formed on the metal layer with application of remote plasma. In some embodiments, the nano-graphene layer is selectively deposited on the metal layer relative to dielectric surfaces or other non-metal surfaces of the substrate. In some implementations, the nano-graphene layer may be a low-quality nano-graphene layer. The low-quality nano-graphene layer may be characterized by D and G peaks in a Raman spectrum. A 2D peak may be negligible or missing in the Raman spectrum.

In some implementations, the one or more hydrocarbon precursors are with other species into the remote plasma source. In some implementations, the one or more hydrocarbon precursors can be mixed with an inert gas such as helium, neon, argon, krypton, or xenon.

In some implementations, the one or more hydrocarbon precursors can be mixed with hydrogen gas. The source gas can include a gas mixture of hydrocarbon precursors and hydrogen gas, where the carbon-containing radicals are generated with hydrogen radicals so that carbon-containing radicals and hydrogen radicals are flowed into the reaction chamber. Hydrogen radicals generated in the remote plasma source may interact with the one or more hydrocarbon precursors to further break down the hydrocarbon precursors. Without being limited by any theory, the hydrogen radicals may selectively break or cleave certain bonds in a hydrocarbon precursor to result in activated alkanes, activated alkenes, or activated alkynes.

By way of an example, one or more hydrocarbon precursors may be delivered to the remote plasma source in a mixture with helium and hydrogen. Hydrocarbon precursors may be supplied to the remote plasma source at a flow rate between about 100 sccm and about 5000 sccm or between about 200 sccm and about 2500 sccm. The hydrocarbon precursors may be flowed with an inert gas such as helium. Helium may be supplied to the remote plasma source at a flow rate between about 1000 sccm and about 36000 sccm. In some cases, a concentration of helium may be at least two times greater than a concentration of the one or more hydrocarbon precursors. Additional gases may be flowed with the one or more hydrocarbon precursors. Hydrogen may be optionally supplied at a flow rate between about 1000 sccm and about 9000 sccm. A concentration of hydrogen may be greater than a concentration of the one or more hydrocarbon precursors. In some embodiments, a pressure in the reaction chamber may be between about 0.5 Torr and about 20 Torr or between about 1 Torr and about 8 Torr.

The one or more hydrocarbon precursors may flow into the reaction chamber through one or more gas ports fluidly coupled to the remote plasma source. In some embodiments, the formation of the nano-graphene layer by plasma deposition using the one or more hydrocarbon precursors is performed using a remote plasma processing apparatus, an example of which is described with reference to FIG. 6. Accordingly, the reaction chamber for performing pretreatment at block 522 may be the same as performing plasma deposition at block 524. In fact, the reaction chamber for performing plasma deposition at block 524 may be the same as performing plasma treatment at block 526. The remote plasma processing apparatus may be equipped with one or more heaters for maintaining a substrate temperature between about 200° C. and about 400° C. The one or more heaters may be incorporated in the substrate support or wafer pedestal of the reaction chamber. By performing plasma deposition of the nano-graphene layer at block 524 in the same reaction chamber as pretreatment at block 522 and/or plasma treatment at block 526, the process 520 increases throughput, reduces processing costs, eliminates substrate transfers, and avoids vacuum breaks that occur between substrate transfers that may otherwise expose the substrate to unwanted materials, atmosphere, and moisture. In some other implementations, the plasma deposition of the nano-graphene layer at block 524 may be performed in a different reaction chamber but within the same tool as pretreatment at block 522 and/or plasma treatment at block 526. In some other implementations, the plasma deposition of the nano-graphene layer at block 524 may be performed in a different reaction chamber of a different tool than pretreatment at block 522 and/or plasma treatment at block 526.

In some embodiments, the nano-graphene layer may be deposited by plasma deposition for a duration between about 1 second and about 200 seconds, between about 2 seconds and about 100 seconds, or between about 3 seconds and about 50 seconds. Plasma deposition may be shorter when repeated in alternating cycles between plasma deposition at block 524 and plasma treatment at block 526. Or, plasma deposition may be longer when plasma deposition at block 524 and plasma treatment at block 526 are not repeated.

At block 526 of the process 520, the nano-graphene layer is exposed to plasma to treat the nano-graphene layer on the metal layer of the substrate. Aspects of the plasma treatment at block 526 may be identical to aspects of plasma treatment at block 516 of the process 510. Accordingly, the description of plasma treatment of the nano-graphene layer at block 516 of the process 510, which may involve exposure to inert gas plasma to form a high-quality nano-graphene layer, may apply to plasma treatment at block 526 of the process 520.

One aspect of the disclosure is an apparatus configured to accomplish the nano-graphene deposition methods described herein. A suitable apparatus includes hardware for accomplishing the process operations and a system controller having instructions for controlling process operations in accordance with the present disclosure. In some implementations, the apparatus for performing the aforementioned process operations can include a remote plasma source. A remote plasma source provides mild reaction conditions compared to a direct plasma.

FIG. 6 illustrates a schematic diagram of an example plasma processing apparatus with a remote plasma source according to some implementations. The plasma processing apparatus 600 includes the remote plasma source 602 separated from a reaction chamber 604. The remote plasma source 602 is fluidly coupled with the reaction chamber 604 via a showerhead 606, which may also be referred to as a multiport gas distributor. Radical species are generated in the remote plasma source 602 and supplied to the reaction chamber 604. One or more hydrocarbon precursors may be supplied to the reaction chamber 604 downstream from the remote plasma source 202 and downstream from the showerhead 606. The one or more hydrocarbon precursors adsorb on a metal layer of a substrate 612 in a chemical vapor deposition zone 608 of the reaction chamber 604 to deposit nano-graphene on the substrate 612. The chemical vapor deposition zone 608 includes an environment adjacent to the front surface of the substrate 612, where the front surface of the substrate 612 faces the remote plasma source 602.

The substrate 612 is supported on a substrate support or pedestal 614. The pedestal 614 may move within the reaction chamber 604 to position the substrate 612 within the chemical vapor deposition zone 608. In the embodiment shown in FIG. 6, pedestal 614 is shown having elevated the substrate 612 within the chemical vapor deposition zone 608. The pedestal 614 may also adjust the temperature of the substrate 612 in some embodiments, which can provide some selective control over thermally activated surface reactions on the substrate 612. For instance, the pedestal 614 may maintain a temperature of the substrate 612 in a range of 200° C. to 400° C. during processing.

FIG. 6 shows a coil 618 arranged around the remote plasma source 602, where the remote plasma source 602 includes an outer wall (e.g., quartz dome). The coil 618 is electrically coupled to a plasma generator controller 622, which may be used to form and sustain plasma within a plasma region 624 via inductively coupled plasma generation. In some implementations, the plasma generator controller 622 may include a power supply for supplying power to the coil 618, where the power can be in a range between about 1 and 6 kilowatts (kW) during plasma generation. In some implementations, electrodes or antenna for parallel plate or capacitively coupled plasma generation may be used to generate a continuous supply of radicals via plasma excitation rather than inductively coupled plasma generation. Regardless of the mechanism used to ignite and sustain the plasma in the plasma region 624, radical species may continuously be generated using plasma excitation during film deposition. In some implementations, helium or hydrogen/helium radicals are generated under approximately steady-state conditions during steady-state film deposition or steady-state film treatment.

A supply of inert gas radicals may be continuously generated within the plasma region 624 while inert gas or other source gas is being supplied to the remote plasma source 602. Excited inert radicals may be generated in the remote plasma source 602. If not re-excited or re-supplied with energy, or re-combined with other radicals, the excited inert gas radicals lose their energy, or relax. Thus, excited inert gas radicals may relax to form inert gas radicals in a substantially low energy state or ground state.

Inert gas or other source gas may be diluted with one or more additional gases. These one or more additional gases may be supplied to the remote plasma source 602. In some implementations, the inert gas or other source gas is mixed with one or more additional gases to form a gas mixture, where the one or more additional gases can include hydrogen, oxygen, or combinations thereof. In certain embodiments, helium gas is mixed with hydrogen. As an example, helium gas is mixed with hydrogen at a concentration of about 1-25% hydrogen or about 1-10% hydrogen.

As shown in FIG. 6, a source gas supply 626 is fluidly coupled with the remote plasma source 602 for supplying the helium gas or other source gas. In addition, an additional gas supply 628 is fluidly coupled with the remote plasma source 602 for supplying the one or more additional gases. The one or more additional gases may include, for example, oxygen and hydrogen. While the embodiment in FIG. 6 depicts the gas mixture of the inert gas and the one or more additional gases being introduced through separate gas outlets, it will be understood that the gas mixture may be introduced directly into the remote plasma source 602. That is, a pre-mixed dilute gas mixture may be supplied to the remote plasma source 602 through a single gas outlet.

Gases, such as excited helium radicals and relaxed gases/radicals, flow out of the remote plasma source 602 and into the reaction chamber 604 via the showerhead 606. Gases within the showerhead 606 and within the reaction chamber 604 are generally not subject to continued plasma excitation therein. In some implementations, the showerhead 606 includes an ion filter and/or a photon filter. Filtering ions and/or photons may reduce substrate damage, undesirable re-excitation of molecules, and/or selective breaking of bonds in nano-graphene. Showerhead 606 may have a plurality of gas ports 644 to diffuse the flow of gases into the reaction chamber 604. In some implementations, the plurality of gas ports 644 may be mutually spaced apart. In some implementations, the plurality of gas ports 644 may be arranged as an array of regularly spaced apart channels or through-holes extending through a plate separating the remote plasma source 602 and the reaction chamber 604. The plurality of gas ports 644 may smoothly disperse and diffuse exiting radicals from the remote plasma source 602 into the reaction chamber 604.

Typical remote plasma sources are far removed from reaction vessels. Consequently, radical extinction and recombination, e.g., via wall collision events, may reduce active species substantially. In contrast, in some implementations, dimensions for the plurality of gas ports 644 may be configured in view of the mean free path or gas flow residence time under typical processing conditions to aid the free passage of radicals into the reaction chamber 604. In some implementations, openings for the plurality of gas ports 644 may occupy between about 5% and about 20% of an exposed surface area of the showerhead 606. In some implementations, the plurality of gas ports 644 may each have an axial length to diameter ratio of between about 3:1 and 10:1 or between about 6:1 and about 8:1. Such aspect ratios may reduce wall-collision frequency for radical species passing through the plurality of gas ports 644 while providing sufficient time for a majority of excited state radical species to relax to ground state radical species. In some implementations, dimensions of the plurality of gas ports 644 may be configured so that the residence time of gases passing through the showerhead 606 is greater than the typical energetic relaxation time of an excited state radical species. Excited state radical species for helium source gas may be denoted by ·He* in FIG. 6.

In some implementations, excited state radical species exiting the plurality of gas ports 644 may flow into a relaxation zone 638 contained within an interior of the reaction chamber 604. The relaxation zone 638 is positioned upstream of the chemical vapor deposition zone 608 but downstream of the showerhead 606. Substantially all or at least 90% of the excited state radical species exiting the showerhead 606 will transition into relaxed state radical species in the relaxation zone 638. Put another way, almost all of the excited state radical species entering the relaxation zone 638 become de-excited or transition into a relaxed state radical species (e.g., ground state radicals) before exiting the relaxation zone 638. In some implementations, process conditions or a geometry of the relaxation zone 638 may be configured so that the residence time of radical species flowing through the relaxation zone 638, e.g., a time determined by mean free path and mean molecular velocity, results in relaxed state radical species flowing out of the relaxation zone 638.

With the delivery of radical species to the relaxation zone 638 from the showerhead 606, one or more hydrocarbon precursors may be introduced into the chemical vapor deposition zone 608. The one or more hydrocarbon precursors may be introduced via a gas distributor or gas outlet 642, where the gas outlet 642 may be fluidly coupled with a precursor supply source 640. The relaxation zone 638 may be contained within a space between the showerhead 606 and the gas outlet 642. The gas outlet 642 may include mutually spaced apart openings so that the flow of the one or more hydrocarbon precursors may be introduced in a direction parallel with gas mixture flowing from the relaxation zone 638. The gas outlet 642 may be located downstream from the showerhead 606 and the relaxation zone 638. The gas outlet 642 may be located upstream from the chemical vapor deposition zone 608 and the substrate 612. The chemical vapor deposition zone 608 is located within the interior of the reaction chamber 604 and between the gas outlet 642 and the substrate 612. Substantially all of the flow of the one or more hydrocarbon precursors may be prevented from mixing with excited state radical species adjacent to the showerhead 606.

In some implementations, a co-reactant may be introduced from the showerhead 606 and flowed along with the radical species generated in the remote plasma source 602 and into the reaction chamber 604. This may include radicals and/or ions of a co-reactant gas provided in the remote plasma source 602. The co-reactant may be supplied from the additional gas supply 628. In some implementations, the co-reactant may include a nitrogen-containing agent such as nitrogen gas (N₂). In some implementations, the co-reactant may include an oxygen-containing agent such as oxygen gas (O₂). In some implementations, the co-reactant may include a hydrogen-containing agent such as hydrogen gas (H₂).

The gas outlet 642 may be separated from the showerhead 606 by a sufficient distance to prevent back diffusion or back streaming of the one or more hydrocarbon precursors. This can afford sufficient time for radical species of helium or hydrogen to transition from an excited state to a relaxed state (e.g., ground state). In some implementations, the gas outlet 642 may be separated from the plurality of gas ports 644 by a distance between about 0.5 inches and about 5 inches, or between about 1.5 inches and about 4.5 inches, or between about 1.5 inches and about 3 inches.

Process gases may be removed from the reaction chamber 604 via an outlet 648 that is fluidly coupled to a pump (not shown). Thus, excess hydrocarbon precursors, co-reactants, radical species, and diluent and displacement or purge gases may be removed from the reaction chamber 604. In some implementations, a system controller 650 is in operative communication with the plasma processing apparatus 600. In some implementations, the system controller 650 includes a processor system 652 (e.g., microprocessor) configured to execute instructions held in a data system 654 (e.g., memory). In some implementations, the system controller 650 may be in communication with the plasma generator controller 622 to control plasma parameters and/or conditions. In some implementations, the system controller 650 may be in communication with the pedestal 614 to control pedestal elevation and temperature. In some implementations, the system controller 650 may control other processing conditions, such as RF power settings, frequency settings, duty cycles, pulse times, pressure within the reaction chamber 604, pressure within the remote plasma source 602, gas flow rates from the source gas supply 626 and the additional gas supply 628, gas flow rates from the precursor supply source 640 and other sources, temperature of the pedestal 614, and temperature of the reaction chamber 604, among others.

The controller 650 may contain instructions for controlling process conditions for the operation of the plasma processing apparatus 600. The controller 650 will typically include one or more memory devices and one or more processors. The processor may include a CPU or computer, analog and/or digital input/output connections, stepper motor controller boards, etc. Instructions for implementing appropriate control operations are executed on the processor. These instructions may be stored on the memory devices associated with the controller 650 or they may be provided over a network.

In certain embodiments, the controller 650 controls all or most activities of the plasma processing apparatus 600 described herein. For example, the controller 650 may control all or most activities of the plasma processing apparatus 600 associated with depositing nano-graphene and treating nano-graphene. The controller 650 may execute system control software including sets of instructions for controlling the timing, gas composition, gas flow rates, chamber pressure, chamber temperature, RF power levels, substrate position, and/or other parameters. Other computer programs, scripts, or routines stored on memory devices associated with the controller 650 may be employed in some embodiments. To provide relatively mild reactive conditions at the environment adjacent to the substrate 612, parameters such as the RF power levels, gas flow rates to the plasma region 624, gas flow rates to the chemical vapor deposition zone 608, temperature of the pedestal 614, and timing of the plasma ignition can be adjusted and maintained by controller 650. Additionally, adjusting the substrate position may further reduce the presence of high-energy radical species at the environment adjacent to the substrate 612. In a multi-station reactor, the controller 650 may comprise different or identical instructions for different apparatus stations, thus allowing the apparatus stations to operate either independently or synchronously.

In some embodiments, the controller 650 may include instructions for performing operations such as flowing one or more hydrocarbon precursors through the gas outlet 642 into the reaction chamber 604 to adsorb onto a metal layer of the substrate 612 to produce nano-graphene on the metal layer, providing a source gas in the remote plasma source 202, generating one or more radical species of the source gas in the remote plasma source 602 upstream of the one or more hydrocarbon precursors, introducing the one or more radical species from the remote plasma source 602 into the reaction chamber 604 to treat the nano-graphene on the surface of the substrate 612. The one or more radical species may be inert gas radical species in the reaction chamber 604. In some implementations, the controller 650 may include instructions for pretreating the metal layer of the substrate 612 prior to depositing nano-graphene. In some implementations, the controller 650 may include instructions for maintaining a temperature of the substrate 612 equal to or less than about 500° C., or between about 200° C. and about 400° C. In some implementations, each of the one or more hydrocarbon precursors includes an alkene or alkyne group.

In some embodiments, the plasma processing apparatus 600 may include a user interface associated with controller 650. The user interface may include a display screen, graphical software displays of the apparatus 600 and/or process conditions, and user input devices such as pointing devices, keyboards, touch screens, microphones, etc.

The computer program code for controlling the above operations can be written in any conventional computer readable programming language: for example, assembly language, C, C++, Pascal, Fortran, or others. Compiled object code or script is executed by the processor to perform the tasks identified in the program.

Signals for monitoring the process may be provided by analog and/or digital input connections of the system controller. The signals for controlling the process are output on the analog and digital output connections of the processing system.

In general, the methods described herein can be performed on systems including semiconductor processing equipment such as a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. In general, the electronics are referred to as the controller, which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials (e.g., silicon carbide), surfaces, circuits, and/or dies of a wafer.

The controller, in some implementations, may be apart of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

FIG. 7 shows a schematic diagram of an example plasma processing apparatus having a reaction chamber with pedestal heating according to some implementations. As shown in FIG. 7, a plasma processing apparatus 700 includes a reaction chamber 724, which encloses other components of the apparatus 700 and serves to contain the plasma. The reaction chamber 724 includes a showerhead 714 for delivering process gases into the reaction chamber 724. A high-frequency radio-frequency (HFRF) generator 702 may be connected to an impedance matching network 706, which is connected to the showerhead 714. In some implementations, a low-frequency radio-frequency (LFRF) generator 704 may be connected to the impedance matching network 706 to connect to the showerhead 714. The power and frequency supplied by the impedance matching network 706 is sufficient to generate a plasma from the process gas. In typical processes, a frequency generated by the HFRF generator 702 is between about 2-60 MHz, such as 13.56 MHz or 27 MHz. A frequency generated by the LFRF generator 202 is between about 250-400 kHz, such as 350 kHz or 400 kHz.

The reaction chamber 724 further includes a wafer support or pedestal 718. The pedestal 718 can support a wafer 716. The pedestal 718 can include a chuck, a fork, and/or lift pins to hold the wafer 716 during and between processing. In some implementations, the chuck may be an electrostatic chuck. In some implementations, the pedestal 718 further includes one or more heating elements (not shown) such as one or more resistance heaters to control a temperature of the wafer 716. The one or more heating elements may maintain the temperature of the wafer 716 at temperatures between about 200° C. and about 400° C. during deposition and treatment of nano-graphene.

Process gases are introduced via inlet 712. One or more source gas lines 710 can be connected to a manifold 708. The process gases may be premixed or not. Appropriate valving and mass flow control mechanisms are employed to ensure that the correct gases are delivered during deposition, etch, and other plasma treatment operations. Process gases may exit the reaction chamber 724 via an outlet 722. A vacuum pump 726 can typically draw process gases out and maintain a suitably low pressure within the reaction chamber 724.

As shown in FIG. 7, the plasma processing apparatus 700 is a capacitor type system where the showerhead 714 is an electrode working in conjunction a grounded block 720. In other words, the plasma processing apparatus 700 is a CCP system and may be capable of supplying high-frequency RF power to the top of the reaction chamber 724, namely the showerhead 714. The bottom of the reaction chamber 724, namely the pedestal 718 and the block 720, is grounded.

In addition to nano-graphene deposition described herein, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Raman spectroscopy can be used for the characterization of graphene or nano-graphene. Raman spectroscopy can also be suitable for determining the number of graphene layers as well as the amount of disorder in graphene. By identifying certain features of graphene or nano-graphene in a Raman spectrum, graphene or nano-graphene can be distinguished from disordered or amorphous carbon layers.

### CONCLUSION

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of depositing nano-graphene, the method comprising:
flowing one or more hydrocarbon precursors into a reaction chamber to adsorb onto a metal layer of a substrate at a temperature equal to or less than about 400° C., wherein the metal layer interacts with the adsorbed hydrocarbon precursors to produce a nano-graphene layer on the metal layer; and
exposing the nano-graphene layer to plasma to treat the nano-graphene layer on the metal layer of the substrate.

2. The method of claim 1, wherein exposing the nano-graphene layer to plasma comprises treating the nano-graphene layer with inert gas plasma generated from a remote plasma source to form a high-quality nano-graphene layer.

3. The method of claim 1, wherein the metal layer comprises copper, ruthenium, nickel, molybdenum, cobalt, or combinations thereof.

4. The method of claim 3, wherein the metal layer comprises cobalt.

5. The method of claim 1, wherein the one or more hydrocarbon precursors comprise an unsubstituted alkene, a substituted alkene, aromatic hydrocarbon, an unsubstituted alkyne, or substituted alkyne group.

6. The method of claim 5, wherein the one or more hydrocarbon precursors comprise toluene, benzene, ethylene, propylene, butene, pentene, pentadiene, hexene, acetylene, propyne, butyne, or pentyne.

7. The method of claim 1, wherein the one or more hydrocarbon precursors comprise propadiene, allene, cyclopropene, 1,3-butadiene, 1,2-butadiene, cyclobutene, isoprene, piperylene, cyclohexene, dimethylbutadiene, 1,5-hexadiene, norbornene, or 1,7-octadiene.

8. The method of claim 1, wherein flowing the one or more hydrocarbon precursors into the reaction chamber comprises flowing the one or more hydrocarbon precursors with hydrogen-helium (H₂—He) into the reaction chamber.

9. The method of claim 1, wherein flowing the one or more hydrocarbon precursors into the reaction chamber comprises flowing the one or more hydrocarbon precursors with oxygen (O₂) into the reaction chamber.

10. The method of claim 1, wherein exposing the nano-graphene layer to plasma comprises exposing the nano-graphene layer to remote hydrogen-helium plasma.

11. The method of claim 1, wherein exposing the nano-graphene layer to plasma comprises exposing the nano-graphene layer to remote oxygen-helium plasma.

12. The method of claim 1, wherein a thickness of the metal layer is between 10 Å and about 20 Å.

13. The method of claim 1, further comprising:
pretreating the metal layer with plasma to reduce metal oxides from the metal layer prior to flowing the one or more hydrocarbon precursors into the reaction chamber.

14. The method of claim 1, further comprising:
repeating operations of flowing one or more hydrocarbon precursors into the reaction chamber and plasma exposure in order to form a desired thickness of the nano-graphene layer on the metal layer of the substrate.

15. A method of depositing nano-graphene, the method comprising:
flowing carbon-containing radicals into a reaction chamber to expose a metal layer of a substrate to the carbon-containing radicals, wherein the carbon-containing radicals are generated from a source gas comprising one or more hydrocarbon precursors in a remote plasma source upstream of the reaction chamber, and wherein the metal layer interacts with the carbon-containing radicals to produce a nano-graphene layer on the metal layer; and
exposing the nano-graphene layer to plasma to treat the nano-graphene layer on the metal layer of the substrate.

16. The method of claim 15, wherein exposing the nano-graphene layer to plasma comprises treating the nano-graphene layer with inert gas plasma generated from a remote plasma source to form a high-quality nano-graphene layer.

17. The method of claim 15, wherein the source gas comprises a mixture of hydrogen (H₂) and the one or more hydrocarbon precursors, wherein carbon-containing radicals and hydrogen radicals are generated in the remote plasma source and flowed into the reaction chamber.

18. The method of claim 15, wherein the metal layer comprises copper, ruthenium, nickel, molybdenum, cobalt, or combinations thereof.

19. The method of claim 18, wherein the metal layer comprises cobalt.

20. The method of claim 15, wherein the one or more hydrocarbon precursors comprise an unsubstituted alkene, a substituted alkene, aromatic hydrocarbon, an unsubstituted alkyne, or substituted alkyne group.

21. The method of claim 20, wherein the one or more hydrocarbon precursors comprise toluene, benzene, ethylene, propylene, butene, pentene, pentadiene, hexene, acetylene, propyne, butyne, or pentyne.

22. The method of claim 15, wherein the one or more hydrocarbon precursors comprise propadiene, allene, cyclopropene, 1,3-butadiene, 1,2-butadiene, cyclobutene, isoprene, piperylene, cyclohexene, dimethylbutadiene, 1,5-hexadiene, norbornene, or 1,7-octadiene.

23. The method of claim 15, wherein exposing the nano-graphene layer to plasma comprises exposing the nano-graphene layer to remote hydrogen-helium plasma or remote oxygen-helium plasma.
